(19) United States
(12) Patent Application Publication
(10) Pub. No.: US 2002/0018502 A1
(43) Pub. Date: Feb. 14, 2002

(54) Semiconductor lasers with varied quantum well thickness

(75) Inventor: Rickard Marcks von Wurtemberg, Stockholm (SE)

Correspondence Address: LAW OFFICE OF LAWRENCE E LAUBSCHER, JR, 1160 SPA RD, SUITE 2B, ANNAPOLIS, MD, 21403, US

(73) Assignee: Mitel Semiconductor AB, Jarfalla (SE)

(21) Appl. No.: 09/883,468

(22) Filed: Jun. 18, 2001

(30) Foreign Application Priority Data
Jun. 20, 2000 (GB) 0014933.6

(51) Int. Cl. H01S 3/08; H01S 5/00

(52) U.S. Cl. 372/45; 372/96

(57) ABSTRACT

An optical emission device includes a semiconductor with conduction and valence bands and a plurality of quantum wells formed in the conduction and valence bands in a multiple quantum well active region such that recombination of holes and electrons between said quantum wells results in the emission of light. At least some of the quantum wells have different characteristic emission frequencies to broaden the gain spectrum of the emitted light.

### FIELD OF THE INVENTION

This invention relates to optical emission devices, such as lasers, and in particular but no exclusively to VCSELs (Vertical Cavity Surface Emitting Lasers).

### BACKGROUND OF THE INVENTION

The difference between the gain (photoluminescence) peak wavelength and the cavity resonance wavelength of a VCSEL has a major impact of the temperature performance of the component. This is because the two wavelengths mentioned above shift at different rates when the temperature of the component is changed. Therefore, the difference between the wavelengths changes with temperature. The variation with temperature of the output power and threshold current is a major problem in VCSELs.

It is possible to make VCSELs that meet the standard telecom temperature operating range of 0-70° C. with structures that are well described in literature. However, if such structures are used, the uniformity requirements on epitaxial wafer manufacturing are very strict and it is hard to achieve good yield at a low cost and/or meet a future wider temperature range specification.

An object of the invention is to reduce this variation for a given temperature interval or to extend the temperature interval in which the VCSEL can be operated.

### SUMMARY OF THE INVENTION

According to the present invention there is provided an optical emission device comprising a semiconductor having conduction and valence bands, and a plurality of quantum wells formed in said conduction and valence bands in a multiple quantum well active region such that recombination of holes and electrons between said quantum wells results in the emission of light, wherein at least some of said quantum wells have different characteristic emission frequencies to broaden the gain spectrum of the emitted light.

In this specification the term “optical” includes infrared and similar wavelengths. The invention is not limited to the visible spectrum.

Preferably, the different quantum wells in the multiple quantum well active region of a VCSEL have different widths, causing the gain spectrum to be broadened. This simplifies the alignment of the gain spectrum with the cavity resonance wavelength, which is required for lasing. Also, because the gain spectrum and the cavity resonance both vary with temperature at different rates, their alignment varies with temperature. This causes the performance of the VCSEL to vary with temperature as well; e.g. the threshold current will vary parabolicaly with temperature with a minimum for some temperature. If the gain spectrum is broadened, the curvature of the parabola is decreased; i.e. the variation of the threshold current with temperature is decreased.

The number of quantum wells can be varied but must be equal to or larger than two. Not all of them need to have different thickness, but at least two. Not all of the quantum wells need to be made out of the same material, but different compositions of e.g. AlGaAs may be used. The quantum wells do not have to be placed in any kind of order, i.e. the thickest to one side and the thinnest to the other side. Also, it does not matter how the different quantum wells are placed with respect to the p- or n-side of the junction. All this applies to the barriers between the quantum wells as well, i.e. they can be of different thickness or composition and they do not have to be placed in any particular order.

The invention is not limited to improve the temperature performance of VCSELs, but also improves the temperature performance of DFB (Distributed FeedBack) and DBR (Distributed Bragg Reflector) edge-emitting lasers which suffer from exactly the same problems as VCSELs. Furthermore, the invention might be used to increase the spectral width of light emitting diodes and to improve the temperature performance of RCLEDs (Resonant Cavity Light Emitting Diodes).

The invention also provides a method of broadening the gain spectrum of an optical emission device, comprising providing a plurality of quantum wells in an active region of a semiconductor, and forming at least some of said quantum wells with different characteristic emission frequencies so as to broaden the gain spectrum of the device.

### BRIEF DESCRIPTION OF THE DRAWINGS

The invention will now be described in more detail, by way of example only, with reference to the accompanying drawings, in which:

FIG. 1 shows the normalized gain spectrum for an active region with quantum wells of the same thickness;

FIG. 2 shows the normalized gain spectrum for an active region with quantum wells of different thickness;

FIG. 3 shows the photoluminescence curves for VCSELS with quantum wells of the same thickness and different thickness;

FIGS. 4a and 4b are diagrams illustrating an active region with the same and different thicknesses.

### DETAILED DESCRIPTION OF THE PREFERRED EMBODIMENTS

The gain of a standard VCSEL was increased by introducing a split between the eigenenergies of the three subbands associated with the three quantum wells active region. This split was introduced by varying the thicknesses of the different quantum wells. In theory, this kind of broadening of the gain spectrum does not come without a negative impact on the threshold current. This is because the current injected into the device is proportional to the area under the gain spectrum curve. The threshold current condition, on the other hand, is satisfied when the gain spectrum curve reaches a certain amplitude at the etalon frequency. A broadening of the gain spectrum increases the area under it if the amplitude at the etalon frequency is kept constant. Thus the threshold current is increased.

To counteract this increase of the threshold current the following change was made to the structure of the VCSEL: the number of periods in the top DBR was increased from 20 to 23. This should (theoretically) increase the reflectivity of the top DBR and thereby reduce the threshold current.

Results from this experiment have been very encouraging. ⅛ of a wafer was processed and probed in a new waferprober MULDER. At 25° C., 99,5% of the components had a threshold current below 5 mA. At 70° C., 99,9% of the components had a threshold current below 6 mA. At the same time, approximately 95% of the components had a power drop of less than 30% between 25° C. and 70° C. at 12 mA drive current. This is the highest yield ever reported for a VCSEL wafer processed by the applicants.

Experimental set-up

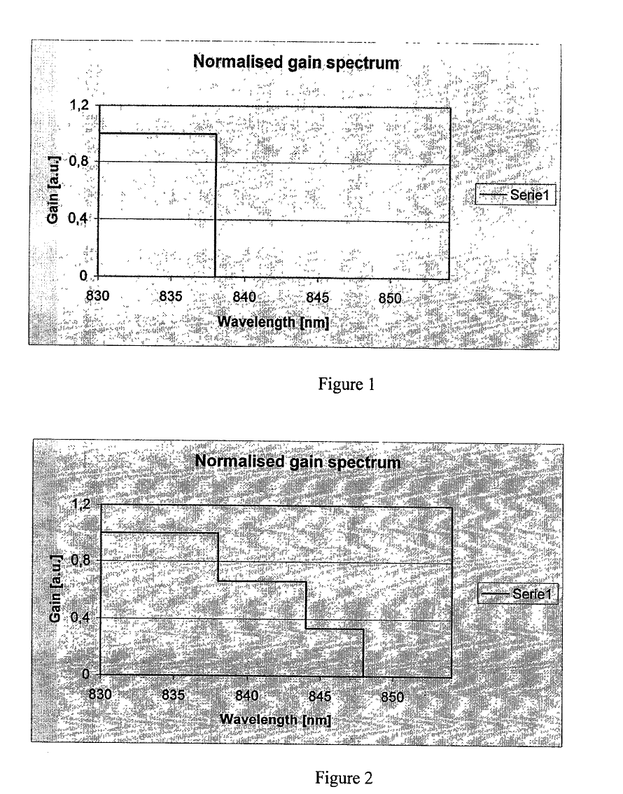

According to calculations, the active region of a conventional Mitel VCSEL has a carrier density of states spectrum that consist of the sum of three Heaviside stepfunctions, all with onsets at a photon energy of E=1,49 [eV] corresponding to a photon wavelength of λ=832 [nm]. Since then, the quantum well thickness has been increased from 6 [nm] to 7[nm] to shift the onsets of the Heaviside stepfunctions from λ=832 [nm]. Since the gain of the active region is proportional to the carrier density of states, the gain spectrum is also described by the Heaviside stepfunctions mentioned above as shown in FIG. 1.

As can be seen in FIG. 1, no lasing can occur for wavelengths below 838 nm since the gain is zero. This might seem strange, considering that Mitel VCSELs usually lase at a wavelength of around 850 nm. The explanation is that the gain spectrum is broadened by thermal vibrations of the lattice. This enables lasing at wavelengths above 838 nm. However, the thermal broadening converts the infinite slope of the Heaviside stepfunction to a finite but steep slope. This causes the threshold current of a device to be very sensitive to the lasing wavelength.

To make the slope less steep, the the thicknesses of the quantum wells are made different. This splits the onset wavelengths of the Heaviside stepfunctions. By choosing quantum well thicknesses of 7, 8 and 9 nm for the three different wells, onset wavelengths of 838, 844 and 848 nm are achieved, resulting in the gain spectrum shown in FIG. 2.

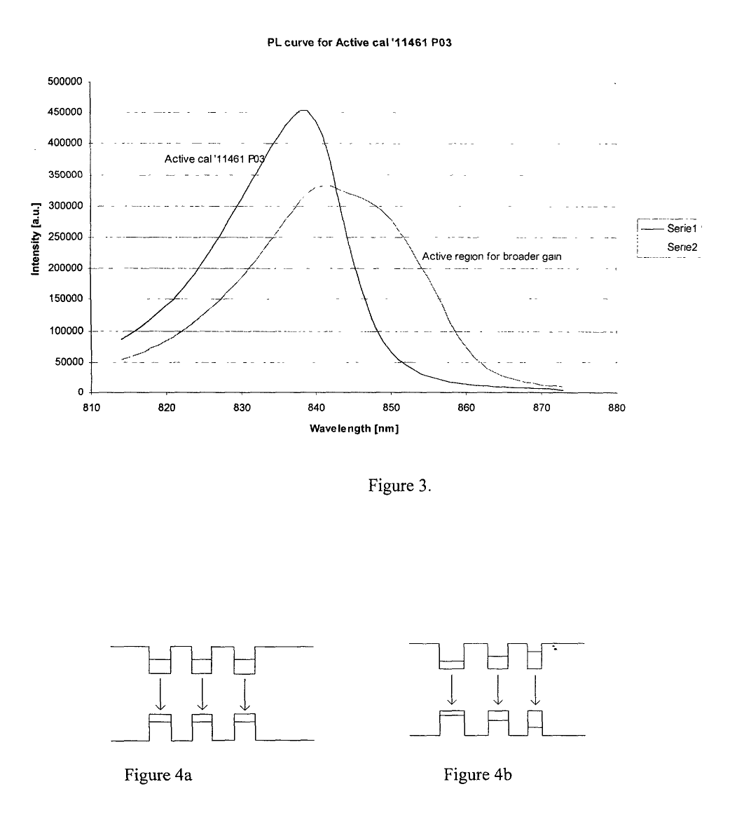

A semi-empirical method was used to estimate the thermal broadening of the gain spectrum. Three active region calibration gain spectrums obtained by photoluminesence from a standard VCSEL active region with equally thick quantum wells was superimposed, two of them with offsets of 6 and 10 [nm] respectively. The result is shown in FIG. 3. The two curves have been normalised to have the same area.

The specification for the structure, which was grown by EPI, is EPIQ9718461. Seven wafers were delivered with numbers EPIQ9718461#1-7. These were given Mitel numbers 3248-3254. The FWHM of the PL (Photoluminescence) curve of the active layer calibration was 25,5 nm to be compared with the semi-empirically estimated value of 28,7 nm (FIG. 3) and the standard value of 19,0 nm (FIG. 3). One quarter (“A”) from wafer 3248 was processed (run #J12810.1) using Mitel wafer process #106906. After the wafer process, the quarter was split into two parts. One part was cleaved and mounted in TO-46 headers. The other part was probed in the waferprober MULDER.

FIG. 4a shows a multiple quantum well active region 10 where all the quantum wells 3 (in this case three) have the same thickness. Thus, the bottom 4 of all three electron subbands have the same energy compared to the bottoms 5 of the wells 3. The same applies to the tops 6 of all three hole. FIG. 4a shows the situation if the thickness of each quantum well is made different from the others. As can be seen, the energies of the bottoms (tops) of the different subbands are now different. That the highest subband energies are marked in the thinnest wells is because the probability of finding an electron with the highest subband energy is highest in the thinnest well.

1. An optical emission device comprising a semiconductor having conduction and valence bands, and a plurality of quantum wells formed in said conduction and valence bands in a multiple quantum well active region such that recombination of holes and electrons between said quantum wells results in the emission of light, wherein at least some of said said quantum wells have different characteristic emission frequencies to broaden the gain spectrum of the emitted light.

2. An optical emission device as claimed in claim 1, wherein said quantum wells with different characteristic emission frequencies have different widths.

3. An optical emission device as claimed in claim 1, wherein said quantum wells with different characteristic emission frequencies have different barrier thicknesses.

4. An optical emission device as claimed in claim 3, wherein all of said quantum wells have different thicknesses.

5. An optical emission device as claimed in claim 1, wherein said semiconductor is AlGaAs.

6. An optical emission device as claimed in claim 1, wherein said optical emission device is a VCSEL.

7. An optical emission device as claimed in claim 1 including a distributed bragg refelctor (DBR), wherein the number of periods of said DBR is increased relative to a conventional device to increase its reflectivity and thereby reduce threshold current.

8. A method of broadening the gain spectrum of an optical emission device, comprising providing a plurality of quantum wells in an active region of a semiconductor, and forming at least some of said quantum wells with different characteristic emission frequencies so as to broaden the gain spectrum of the device.

9. A method as claimed in claim 8, wherein all of said quantum wells have different characteristic emission frequencies.

10. A method as claimed in claim 8, wherein said quantum wells have different thicknesses.

11. A method as claimed in claim 10, wherein the device has a Distrubuted Bragg Reflector (DBR) and the number of periods of said DBR is increased to increase its reflectivity and thereby reduce threshold current.
